(19) United States
(12) Patent Application Publication
(10) Pub. No.: US 2011/0277809 A1
(43) Pub. Date: Nov. 17, 2011

(54) Modular Tensile Structure with Integrated Photovoltaic Modules

(76) Inventors: Todd Dalland, New York, NY (US); Robert Lerner, Port Washington, NY (US)

(21) Appl. No.: 13/055,409

(22) PCT Filed: Jul. 21, 2009
(86) PCT No.: PCT/US09/51249

§ 371 Date: May 18, 2011

Related U.S. Application Data
(60) Provisional application No. 61/082,475, filed on Jul. 21, 2008.

(51) Int. Cl. H01L 31/042; H01L 31/18

(52) U.S. Cl. 136/244; 29/890.033

(57) ABSTRACT

A tensile structure is provided that includes a plurality of vertical support members, one of the vertical support members being taller than all others of the vertical support members. A plurality of securing members is connected between the vertical support members and ground. A membrane is attached to and extending between the vertical support members to form a roof of the tensile structure, such that one corner of the membrane is raised with respect to the other corners. A plurality of flexible photovoltaic devices are integrated with the membrane.

### CROSS-REFERENCE TO RELATED APPLICATION

This application claims the benefit of U.S. Provisional Patent Application No. 61/082,475, filed Jul. 21, 2008, which is hereby incorporated by reference herein in its entirety. This application is related to U.S. Design patent application Ser. No. 29/297,801, filed Nov. 19, 2007, which is hereby incorporated by reference herein in its entirety.

### BACKGROUND

1. Field of the Invention

The invention relates to modular tensile structures with integrated photovoltaic modules, including structures topped with double-curved membranes having an array of flexible photovoltaic modules affixed thereto.

2. Related Art

Photovoltaic modules convert solar energy into electricity through the photovoltaic effect, which is a process by which the energy contained in photons is converted into electrical current. Photovoltaic modules typically are formed of a semiconductor, such as silicon. Received photons may be absorbed by the semiconductor lattice thereby releasing bound electrons, which then flow as a current. When silicon is used as a light absorbing material in a photovoltaic module, it can be in bulk, crystalline form or a thin film using amorphous silicon. Flexible photovoltaic modules have been produced using thin-film amorphous silicon on a polymer substrate, which may be manufactured as long flexible strips. Such configurations may include a transparent upper conductor, an amorphous silicon layer doped to form a PiN junction, and a lower metal conductive layer all formed on a polymer substrate. Flexible photovoltaic modules have been affixed to fabric to form tent structures, but the design of such structures generally has tended toward maintaining conventional tent architecture, as opposed to taking modularity and solar energy reception characteristics into account.

### SUMMARY

In one aspect, the present invention provides a tensile structure that includes a plurality of vertical support members, one of the vertical support members being taller than all others of the vertical support members. A plurality of securing members is connected between the vertical support members and ground. A membrane is attached to and extending between the vertical support members to form a roof of the tensile structure, such that one corner of the membrane is raised with respect to the other corners. A plurality of flexible photovoltaic devices are integrated with the membrane.

Embodiments of the present invention may include one or more of the following features.

The membrane may be formed of a plurality of elongate sections, each section having concave lengthwise edges and concave end edges. The shapes of the concave lengthwise edges and shapes of the end edges of the sections may be determined based at least in part on a difference between a length of the taller vertical support member and the other vertical support members. The photovoltaic devices may be arranged to allow the membrane to be folded without folding the photovoltaic devices. A difference between a length of the taller vertical support member and the other vertical support members may be determined based at least in part on a desired solar inclination angle. The photovoltaic devices may be arranged in rows and pairs of columns, such that an internal gap within a pair of columns is less than an external gap between pairs of columns. The securing members may include a tensioning device configured to apply variable tension to a vertical support member to which it is connected.

The membrane may comprise fabric, and a shape of the membrane may be compensated for stretching based on stretching characteristics of the fabric. The compensation for stretching may be adjusted based on a determination of areas of the membrane that comprise the photovoltaic devices. The adjustment to the compensation for stretching may be based on separately computing stretch compensation for areas of the membrane comprising the photovoltaic devices and areas of the membrane without the photovoltaic devices. The adjustment to the compensation for stretching may be based on performing an integration, over the area of the membrane, of stretch compensation factors for differential areas of the membrane.

The flexible photovoltaic devices may include photovoltaic modules formed of amorphous silicon on a polymer substrate. The membrane may include fabric, which may be polyester vinyl. The securing members may include cables or webbing belts.

In another aspect, the present invention provides a tensile structure including a horizontal frame having frame elements with vertices, each frame element defining an opening surrounded by horizontal members of the horizontal frame which meet at the vertices. A plurality of vertical support members is provided, each positioned at a vertex of a frame element. A plurality of base support members is connected at vertices of the horizontal frame along a central portion to support the horizontal frame above the ground. A plurality of membranes is provided, each membrane attached to one of the frame elements between the vertical support member and the vertices of the frame element to form a portion of a roof of the tensile structure, such that a corner of the membrane attached to the vertical support member is raised with respect to the other corners. A plurality of flexible photovoltaic devices is integrated with each of the membranes. Embodiments of this aspect of the present invention may include one or more of the features discussed above.

In another aspect, the present invention provides a tensile structure including a plurality of vertical support members arranged to surround a plurality of adjoining areas, one of the vertical support members of each area being taller than all others of the vertical support members of the area. A plurality of securing members is connected between the vertical support members and ground. A plurality of membranes is provided, each membrane attached to and extending between the vertical support members of one of the areas to form a portion of a roof of the tensile structure, such that one corner of the membrane is raised with respect to the other corners. A plurality of flexible photovoltaic devices is integrated with each of the membranes. Embodiments of this aspect of the present invention may include one or more of the features discussed above.

In another aspect, the present invention provides a tensile structure including a vertical support member and at least one securing member connected between the vertical support member and ground. A membrane is provided having one corner attached to the vertical support member and all others of the corners attached to points on the ground, to form a roof of the tensile structure, such that the corner of the membrane attached to the vertical support member is raised with respect to the other corners. A plurality of flexible photovoltaic devices is integrated with the membrane. Embodiments of this aspect of the present invention may include one or more of the features discussed above.

In another aspect, the present invention provides a method of constructing a tensile structure. Embodiments of this aspect of the present invention may include one or more of the features discussed above. In addition, the membrane may include joined sections, and the photovoltaic devices may be integrated with the sections before the sections are joined.

### BRIEF DESCRIPTION OF THE DRAWINGS

FIG. 1 shows an example of a modular tensile structure.

FIG. 2 shows an example of a plan view of the roof of the modular tensile structure of FIG. 1, as it would appear on a flat surface.

FIG. 3 shows an example of a modular tensile structure having a ground-mounted membrane with integrated photovoltaic modules.

FIG. 4 shows an example of a tensile structure formed of modular tensile structures with integrated photovoltaic modules, as depicted in FIG. 1.

FIG. 5 shows an example of a frame-based structure formed using tensile structure modules for covering a parking lot row.

### DETAILED DESCRIPTION

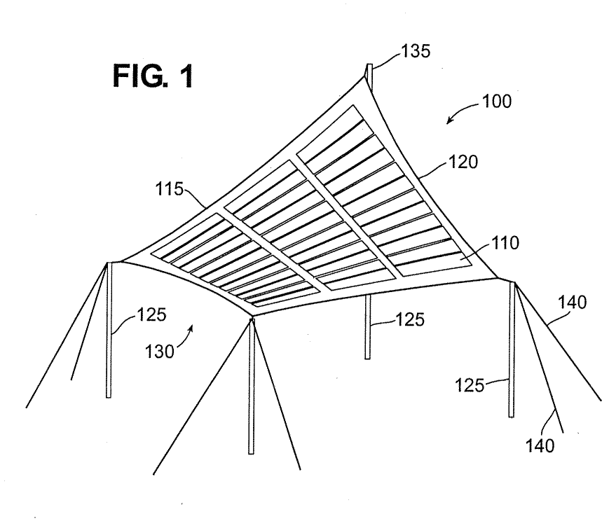

FIG. 1 shows an embodiment of a modular tensile structure 100 with an array of integrated photovoltaic modules 110. The roof 115 of the modular structure 100 is formed of a membrane 120 of fabric suitable for tensile structures, such as, for example, polyester vinyl. The modular tensile structure 100 has various functions relating to its structural characteristics, such as, for example, providing shade, providing protection from precipitation, and managing heat and condensation. In addition, as further discussed below, flexible photovoltaic modules may be integrated with the membrane to produce electrical power from solar energy. The membrane 120 is attached to vertical support members, e.g., support poles 125. In this example, there are four support poles 125, which are attached to the four corners of the membrane 120. The modular structure 100 may have dimensions of, for example, about 20 feet by about 20 feet. The sides 130 of the modular structure 100 may be left open, as shown in FIG. 1, or may be covered by fabric in various configurations to create an enclosed structure.

One of the poles 135 may be taller than all the others to raise one of the corners of the membrane 120 relative to the others and thereby provide a desired curvature to the membrane 120. This configuration provides curvature about both axes in the horizontal plane and therefore results in a double-curved shape, which takes the form of a hyperbolic paraboloid. For example, three of the poles 125 may have a height (i.e., length) of about 8 feet to about 10 feet (typically about 9 feet), while the taller pole 135 has a height (i.e., length) of about 16 feet to about 20 feet (typically about 20 feet). The double-curved shape provides desirable characteristics in terms of shedding rain water and snow and resisting winds. In some embodiments, all of the poles 135 may be the same height, but may have multiple attachment mechanisms on each pole, separated in height, to attach the membrane at the lower height and raised-height positions. The support poles 135 may be interconnected at the top with cables to provide further rigidity to the structure.

Generally speaking, conventional flat solar arrays receive maximum solar energy when directed so that the array surface is normal the direction of the sun. Fixed arrays therefore are usually positioned to face due South (in the northern hemisphere) in order to receive the maximum amount of solar energy over the course of a day. The energy received by such an array varies as the sun traverses the sky, with the maximum occurring at noon. Similarly, a flat solar array should be tilted at a particular angle with respect to vertical in order to maximize the solar energy received over the course of a year, since the inclination of the sun's path changes seasonally. The optimum tilt angle for a flat arrays varies depending upon the latitude of the location of the array.

As discussed above, the roof 115 of the modular structure 100 has a double-curved shape, which results in the membrane 120 having a shape that is curved both along both the direction of the daily solar path and also in an elevation direction. Therefore, as the sun traverses the sky each day, some portion of the array of photovoltaic modules 110 will be normal to the direction of the sun throughout a portion of the day. By contrast, with a flat, fixed array, the entire array is normal to the sun direction only at noon and for the rest of the day, no portion of the array is normal to the sun direction. Similarly, at least a portion of the photovoltaic modules 110 will be normal to the sun, as the inclination angle of the sun changes seasonally.

The tilt angle of the photovoltaic modules 110 affixed to the membrane 120 (i.e., elevation angle) can be adjusted by changing the height (i.e., length) of the support poles 125. For example, if a greater tilt angle (with respect to vertical) is desired, the height of the longest support pole 135 could be increased (or the height of the shorter poles could be decreased, since it is the difference in height between the long pole and the short poles that establishes the shape and inclination of the membrane). Such adjustment would be made prior to the membrane being produced, because it would have a substantial effect on the three-dimensional shape of the installed membrane and thus a corresponding effect on the pattern used to cut the membrane into its initial, uninstalled shape. Another factor to be considered in adjusting the height of the support poles 125 is the shading effect of the membrane 120, i.e., how much shade the membrane 120 may cast on neighboring membranes in a structure formed of adjacent modular structures 100. Yet another factor that might be considered is the effect of snow loading and/or other weather related loads.

The materials used for the membrane 120 and support poles 125 may vary depending upon the application. For example, a lightweight version of the modular structure 100 may be produced for temporary and mobile applications, such as military or recreational applications. The lightweight version may have a membrane 120 formed of lightweight fabric, e.g., Ferrari 502 polyester vinyl or Seaman Corporation Style 8217 Military, 3914 Military, or 6111 Military (all PVC Coated Polyester), and poles 125 formed of lightweight metal, e.g., aluminum. The poles 125 may be collapsible or capable of being disassembled. This version may be particularly useful in applications in which shipping weight is an important factor, such as military and disaster-relief applications.

As a further example, a heavier-weight, architectural version may be produced for more permanent applications, such as architectural applications. The architectural version may have a membrane 120 formed of heavier, more durable material, e.g., Ferrari 1202 T2 polyester vinyl (available from Ferrari SA, La Tour du Pin, France), and poles 125 formed of, e.g., heavier weight aluminum or structural steel. In such applications, shipping weight may not be a significant factor.

The attachment between the membrane 120 and the support poles 125 may be made, for example, using metal shackles connected between a grommet formed in the corner of the membrane 120 and a plate attached to the support pole 125. The corner of the membrane 120 may be reinforced with webbing and/or metal plates.

Each pole 125 has securing members 140, e.g., cables, attached, which are secured between the pole and the ground by various means to help hold the pole 125 in place. For example, in the lightweight version of the modular structure 100, the securing members 140 may be secured to the ground by stakes driven into the ground. The securing members 140 may be attached to the pole 125 by various types of mechanical attachment, such as, for example, by threading the securing member 140 though a hole in a metal plate and securing the end (which may be the same plate to which the membrane 120 is attached). It is also possible to use other structures as securing members, such as, for example, webbing belts, which are woven, narrow-fabric straps, e.g., of woven polyester. Another alternative for the securing members is to use angled poles that have one end secured in the ground and another end connected to the pole 125. In the architectural version, the securing members 140 may be secured to the ground by, for example, attaching the securing members 140 to footings or other anchoring structures (not shown) buried in the ground, e.g., cement footings. Various alternative method of securing the securing members 140 to the ground may be used.

The securing members 140 serve to counteract the tendency of the support poles 125 to bend or tip toward the center of the structure 100 in response to tension forces in the membrane 120. The tension forces in the membrane 120 include “pretension” forces, which are induced in the membrane 120 to help ensure that this normally flexible structural element remains stiff under all possible load conditions. There are also tension forces arising from the self-weight of the membrane 120 and the imposed loads the membrane 120 may carry, e.g., loads due to wind and weather. Various types of tensioning devices may be added at the attachment points of the securing members 140 to the support poles 125, such as turnbuckles, pulley assemblies, webbing belt ratchets, and the like.

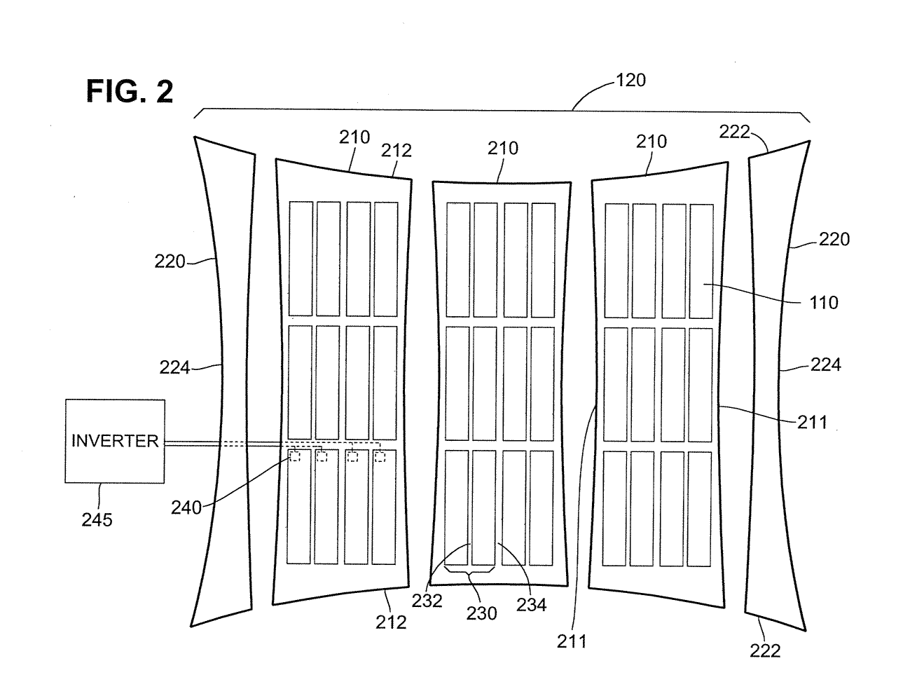

FIG. 2 shows an example of a membrane 120 as it would appear lying on a flat surface, which as discussed below, may be referred to as the cutting pattern. The membrane 120 may be formed of a number of individual panels (210 and 220) of predetermined size and shape. For example, the membrane 120 may be formed of three central sections 210 and two end sections 220 for a total of five sections, but, of course, numerous configurations are possible. The size, shape, and number of sections may be determined based on various considerations, but will generally take into account ease of manufacture and assembly, among other things.

For example, a typical fabric for this type of application is commercially available in five-foot wide rolls. Therefore, each central section 210 may be about 5 feet in width and may be long enough to extend across the entire membrane 120 (the initial length of these sections may be, for example, about 25 feet). The central sections 210 may be joined to each other, e.g., welded, along their lengthwise edges 211. The lengthwise edges 211 and ends 212 of the central sections 210 may be cut to predetermined shapes using computer-controlled cutting equipment, as further discussed below. The two end sections 220 may be joined on the outer, lengthwise edges 211 of the central sections 210 to form the completed membrane 120. These end sections 220 may be cut at their ends 222 and also along their outside, lengthwise edges 224 to form the desired shape of the completed membrane 120.

The completed membrane 120, formed from the separate sections (210 and 220), is configured to have a shape that provides a desired three-dimensional shape when the membrane 120 is attached to the support poles 125. A projected shape of the membrane 120 in the horizontal plane is different than the shape of the membrane 120 lying on a flat surface, because, as noted above, one of the support poles (135) is taller than all the others, which results in three-dimensional curvature of the membrane. Typically, the membrane 120 will be shaped to have an approximately rectangular projected shape in the horizontal plane, such that the projected area is approximately the same size as the area of the tensile structure.

The precise shapes of the membrane 120 and its sections (210 and 220) may be determined using computer software, such as, for example, TENSYL, which is an integrated computer program suite for the form finding, load analysis and cutting pattern generation of tensile structures developed by Buro Happold, Consulting Engineers, Bath UK. The cutting patterns are determined by a number of factors, including the position of the support elements and the level of pretension force at each support.

The cutting pattern may be compensated to account for stretching of the membrane material due to pretension force and environmental stress forces, such as, for example, cyclic stress due to wind loading. Typically, a material will stretch in response to applied forces in accordance with a modulus of elasticity. The amount of stretching for a given applied force may be defined in terms of stretch compensation factors, which are expressed as a percentage increase in length in the warp direction (i.e., the direction of the long yarns of the fabric, which is the direction in which the fabric comes from the roll on which it is supplied) and the fill direction (i.e., the direction perpendicular to the warp direction and parallel to the axis of the roll on which it is supplied). For example, a fabric may have a stretch compensation factor of 0.5% in the warp direction and 1.0% in the fill direction. The stretch compensation factors may be entered into the cutting pattern generation software to generate a compensated pattern, i.e., a cutting pattern in which the dimensions are reduced, so that the fabric will stretch to the correct desired size upon installation. Using an uncompensated cutting pattern, on the other hand, may result in wrinkles or other flaws in the completed tensile structure.

The cutting pattern is also affected by the use of catenary support members along the edges of the membrane, such as, cables (e.g., stainless steel cables), ropes (e.g., Kevlar ropes), and webbing belts, to provide structural support. The catenary support elements allow for greater pretension (or “prestress”) forces to be used in the design, which results in a more rigid tensile structure. Moreover, the increased pretension results in less curvature along the edges of the membrane, which, in turn, provides a larger surface area for the positioning of photovoltaic modules, as further discussed below. In addition, the pretension forces, and the resulting degree of curvature of the membrane, affect the structural stability against wind, snow, earthquake loads and can reduce “flutter” (repetitive concussions associated with flutter can damage the product). The modular structure 100 may be designed for five primary wind and snow load combinations based on conditions in North America and around the world, as opposed to a single combination, as is the case with most conventional structures. A desired tension in the catenary support elements may be specified during the design process, or alternatively, the tension may be calculated from the initially entered design.

Various types of finishing work may be performed on the membrane 120. For example, the corners and edges of the membrane may be reinforced with webbing and/or metal plates, e.g., steel or aluminum. Pockets may be added along the edges of the membrane to hold support cables and/or electrical wiring. For example, cable pockets may be sown along the edges so that electrical cables can be run along the underside of the membrane.

Each of the central sections 210 of the membrane 120 may have an array of integrated photovoltaic (PV) modules, such as, for example, flexible photovoltaic modules 110 formed on polymer substrate. In this example, the PV modules 110 are affixed to the membrane 120, e.g., by adhesive and lamination, but the term “integrated” is intended to broadly cover various means of joining a flexible device with a membrane and/or incorporating a flexible device into a membrane. Thus, the term “devices integrated with the membrane” is intended to cover devices that are affixed to, disposed on, positioned on, or incorporated into the membrane, etc., in various manners.

Each of the central sections 210 may have, for example, three rows of PV modules 110, each row having four PV modules 110, grouped into two pairs 230, with the modules 110 being arranged in each row so that the longer sides are adjacent, as shown in FIG. 2. Each PV module 110 may be, for example, about 1 foot wide and about 4-5 feet long. Alternatively, this arrangement may be described PV modules 110 arranged in rows and pairs of columns. Each pair 230 of PV module 110 columns may be spaced to have an internal gap 232 of, e.g., about 1 inch, with an external gap 234 of, e.g., about 2.5 inches between the column pairs 230. This external gap 234 provides a length-wise channel along each of the central panels 210, which helps allow for the membrane 120 to be foldable without bending and possibly damaging the modules 110. The smaller internal gap 232 allows for the surface of the membrane to be more efficiently covered with PV modules 110. Together, these gaps (232 and 234) between the PV modules 110 also allow for complete lamination around the periphery of each module (as further discussed below). The end sections 220 of the membrane 120 also may have PV modules 110, but do not in this example.

As discussed above, the cutting pattern may be compensated to account for stretching of the membrane material due to pretension force and environmental stress forces. However, the integration of the PV modules with the membrane may substantially decrease the amount of stretching that occurs in the installed membrane, because the PV modules themselves are less elastic than the membrane fabric. Therefore, it may be necessary to adjust the stretch compensation of the membrane 120 to account for this. The adjustment may be computed based on the stretch compensation factors of the membrane fabric (i.e., the warp and fill stretch compensation factors) and the size and position of the modules on the membrane. The areas covered by the modules, and a predefined periphery of these areas, may be treated as having a stretch compensation factor of zero (or a predetermined value, which would be less than the stretch compensation factors of the fabric). The stretching amount of the entire membrane may then be determined based on a two-dimensional integration, performed over the area of the membrane, of the stretching amounts of each differential area of the membrane. Less computationally-intensive methods may also be used to adjust the stretch compensation factors to account for the PV modules.

For example, the adjustment of the stretch compensation of the membrane 120 may be done by computing a stretch-compensated pattern for each section or region of the membrane separately and applying the compensation to the sections that are not substantially covered by PV modules, e.g., the end sections 220 of the membrane 120, but not applying the compensation to the sections that are covered by PV modules, e.g., the central sections 210. It should be noted that the regions of PV modules need not necessarily correspond to actual physical sections of the membrane. It may be necessary to taper the dimensions of the sections approaching the edges where they join, because otherwise there may be a discontinuity in the edges. For example, the length of the central sections 210 may be left at an uncompensated value, while the length of the end sections 220 may be decreased, e.g., by 0.5%, to account for stretching. These lengths may be tapered near the edge joining the central sections 210 and the end sections 220, so that a smooth membrane edge is maintained.

Alternatively, instead of treating the sections or regions of a membrane separately, the stretch compensation factors may be adjusted by an adjustment factor that applies to the entire membrane. For example, if the warp and fill stretch compensation factors for the fabric (i.e., the fabric without PV modules) for a given pretension force are specified to be 0.5% and 1.0%, respectively, then these values may be adjusted to 0.25% and 0.5% to account for the relative lack of stretching of the PV modules. The adjustment may be based on experience with the fabric and modules and/or measured or simulated data.

Flexible photovoltaic modules 110 are available, for example, from PowerFilm, Incorporated of Ames, Iowa (www.powerfilmsolar.com) and Solar Integrated Technologies of Los Angeles, California (www.solarintegrated.com). The PV modules may, for example, be laminated to the membrane as part of a layered assembly, the top layer of which may be a flexible, transparent film, e.g., ethylene tetrafluoroethylene (ETFE) film, which is a thermoplastic fluoropolymer. ETFE film is available, for example, from DuPont (Tefzel®). Other materials may be used for the top layer, such as, for example, polyvinylidene fluoride (PVDF), e.g., from Arkema (Kynar®), fluropolymers, polyesters, polycarbonates, and polyurethanes.

Below the top layer may be a bonding layer, such as, for example, a thermoplastic or pressure sensitive adhesive layer, which bonds the flexible PV module to the top layer. Other materials may be used for the bonding layer, such as, for example, polyethylene, ethylene acrylic acid (EAA) copolymer, polypropylene, acrylic PSA, silicone PSA, clear epoxy films, and various acrylics. U.S. Patent Application Publication No. 2009/0107538 A1 (“the '538 application”), which is hereby incorporated herein by reference in its entirety, discloses other possible sealing materials, such as ethylene vinyl acetate (EVA), an ionomer, or a polyolefin-based adhesive to impart adhesive characteristics during a possible subsequent lamination process. The '538 application also mentions other sealing materials, such as those comprising silicones, silicone gels, epoxies, polydimethyl siloxane (PDMS), RTV rubbers, polyvinyl butyral (PVB), thermoplastic polyurethanes (TPU), acrylics and urethanes. U.S. Patent Application Publication No. 2007/0012353 A1, which is hereby incorporated by reference herein in its entirety, discloses a flexible photovoltaic cell fabrication process in which both the top and bottom encapsulant materials comprise a thermoformable material, such as a thermoplastic polymer, that can be softened by the application of heat and that then re-hardens on cooling. For example, materials comprising polyethylene (PE), polyethylene terephtalate (PET), polyethylene naphthalate (PEN), polycarbonate (PC), polymethyl methacrylate (PMMA), thermoplastic polyurethane (TPU), ethylene tetrafluorethylene (ETFE), or various combinations of such materials.

The PV module may be attached to the fabric using an adhesive, such as, for example, a thermal polyurethane adhesive, e.g., Bemis 5250 (from Bemis Associates Inc.), and/or a layer of epoxy, e.g., from Dow Chemical. If both a thermal polyurethane adhesive and an epoxy are used, the epoxy may be applied to the back of the PV modules, and the thermal polyurethane adhesive may be applied to the fabric. Other adhesive materials may be used to attach the PV module to the fabric, such as, for example, polyurethanes, nylons, polyesters, polyolefins, thermal set adhesives, pressure sensitive adhesives (PSA), acrylics, silicones, rubbers, and synthetics. The fabric, PV modules, and the assembled layers of film and adhesive may be joined using a lamination process in which heat and pressure are applied to the layered structure. The lamination of photovoltaic cells onto fabric is discussed in “Flexible Photovoltaics for Fabric Structures” (AD Number: ADA392505, Corporate Author: Iowa Thin Film Technologies, Personal Author: Jeffrey, Frank, Report Date: Jun. 15, 2001; available at http://stinet.dtic.mil or http://handle.dtic.mil/100.2/ADA392505), which is incorporated herein by reference in its entirety.

It should be noted that while the examples described herein include flexible PV modules, other technologies and devices may also be used for the purpose of converting light energy, e.g., solar energy, into electrical energy. Generally speaking, any technology that is reasonably flexible and that can be integrated with the membrane may be used, including such things as photoactive thin films, dye-sensitized solar cells, organic photovoltaic films, cadmium telluride (CdTe) thin films, copper indium gallium selenide (CIGS) thin films, photosensitive fibers, nanostructures, and biological structures, etc.

The PV modules 110 produce direct current (DC) and may be joined in series, for example, in pairs 230 to provide increased voltage (i.e., the voltage of the pair connected in series is the sum of the voltage produced by each individual module). A pair 230 of PV modules 110 may produce, e.g., about 36 V open circuit and about 30 V at maximum power. PV modules 110 may be connected in series to produce increased current. For example, the PV modules may be connected in series in pairs, and then two pairs may be connected in parallel.

As a rule of thumb, the power produced by a PV module may be estimated as 1000 W/m² at 25° C. times the efficiency of the module, for peak sunlight. The power output of the entire PV array would be equal to the total area of the PV modules (in square meters) times the efficiency times 1000 W, with the power output increasing with decreasing ambient temperature. A 20-foot square modular tensile structure, of the type shown in FIG. 1, might have a total array area of about 13 square feet and would therefore produce about 750 W at 25° C. at peak sun (assuming the modules have an efficiency of about 5%). The energy produced, of course, depends upon the amount of solar energy received in a day, which depends upon many factors, such as latitude and weather. As an example, in Binghamton, N.Y., the modular tensile structure discussed above might produce about 2.5 kWh/day.

A junction box 240 may be provided on the underside of each PV module 110, near the end of the module, to provide an electrical connection point to receive output from the module. Specifically, the junction box 240 may provide an electrical connection through one wire to a transparent upper conductor layer of the module and through another wire to a lower metal conductor layer of the module. The wires may be connected, e.g., by soldering, to contact pads (not shown) on the respective layers of the PV module 110. The junction box 240 covers these connections and helps to make them waterproof, e.g., by using potting material, e.g., silicon. The junction box 240, together with a cover, may be attached to the PV module 110 using a mechanical attachment, such as screws or rivets through the entire PV module, junction box, and cover. The position of the junction box 240 is typically at an end of the PV module 110 and may be staggered across the widths of the PV modules 110 in order to prevent the junction boxes 240 from overlapping when the membrane 120 is folded for shipment.

The wires may extend from the junction box 240 and may terminate in an electrical connector. The wires from each PV module 110 are then connected in series or parallel to form sets of PV modules that produce desired voltage and current levels. The power output of these sets may then be electrically combined to a common wire or run through separate wires to an output device, such as an inverter, which converts the DC into alternating current (AC) for use in AC-powered devices. The wires from the PV modules 110 may be run through wiring pockets formed in the underside of the membrane to the edges of the membrane. As noted above, a number of modular tensile structures 100, as depicted in FIG. 1, may form a larger structure, in which case the output from each modular structure 100 may be electrically connected to form a single power output.

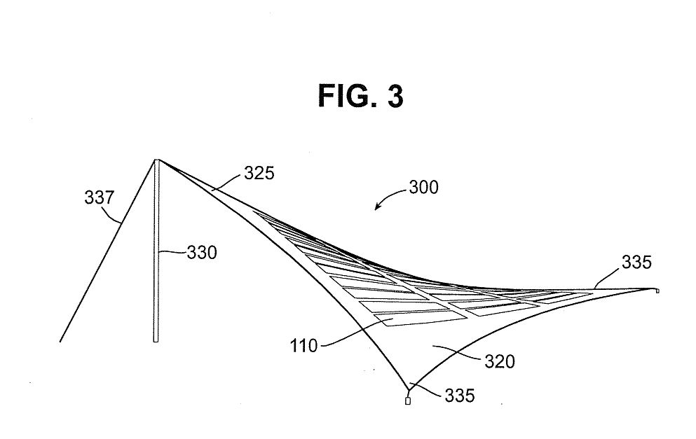

FIG. 3 shows another example of a tensile structure 300 having a ground-mounted membrane 320. In this configuration, the raised corner 325 of the membrane is supported by a pole 330, but the three other corners 335 are directly anchored to the ground. One or more securing members, such as a cable 337, may be secured to the ground to hold the pole 330 in position. Such a configuration might be useful, for example, for military or recreational applications in which it may be desirable to minimize the weight of the structure during transportation by requiring only one pole and little additional hardware for installation. This configuration might also be useful for large scale installations of structures intended only for power generation. In such a case, it may be desirable to minimize the cost of each modular structure, again, by requiring only one pole and little additional hardware to install the structure. Moreover, this configuration also might be suitable for installations subject to high winds or other forms of severe weather, as it presents a lower vertical profile than the structure shown in FIG. 1. In some installations, it may be possible to orient the structure to receive significant amounts of solar energy during the passage of the sun, while at the same time avoiding having a prevailing wind direction toward the raised end of the structure. Yet another application for which this configuration might be suitable would be for installation of modular tensile structures 300 on a flat roof surface.

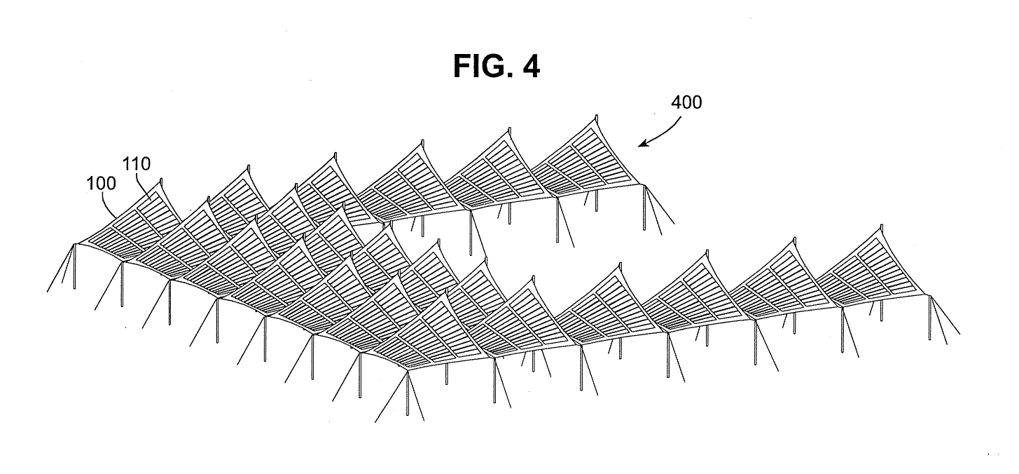

FIG. 4 shows an example of a larger tensile structure 400 formed of modular tensile structures 100, as depicted in FIG. 1. Any number of the modular structures 100 may be grouped in any desired arrangement to create the larger structure 400. The adjacent modular structures 100 may share common support poles, in which case the longer poles may have attachment mechanisms at two positions, i.e., at the top to attach to the raised corner of a membrane and at a lower position to attach to a non-raised corner of an adjacent modular structure 100. In some embodiments, all of the support poles may be the same height, but may have multiple attachment mechanisms separated in height. The support poles may all be interconnected at the top with cables to provide further rigidity to the larger tensile structure 400. The structure 400 may be designed to cover walkways or large open areas or both, among other applications.

Because the modular structures 100 are substantially identical, the larger structure 400 may be constructed using essentially the same techniques as for the modular structures themselves. Uniform techniques for packing, shipping, and unpacking of the modular structures 100 also simplifies construction. In addition, the modular nature of the design allows for the modular structure to be mass-produced indoors using readily available manufacturing equipment and techniques and skilled manpower, which results in various efficiencies and cost savings and increased quality. Such indoor manufacturing resources are available in large scale, which further helps to reduce costs, reduce manufacturing time, and increase quality. Moreover, in contrast to the construction of conventional structures, the indoor construction of the modular structures is largely unaffected by weather, allows for 24 hour/day manufacturing, and increases the opportunity for quality control through repetition and inspection. The relatively small size of the modular structures 100 allows for efficient use of sites with irregular-shaped boundaries or with interior obstructions, such as trees, air conditioning equipment, stairwells, etc. The use of modular structures thus allows for easy scalability of tensile structures to provide shelter and power generation in response to varying requirements.

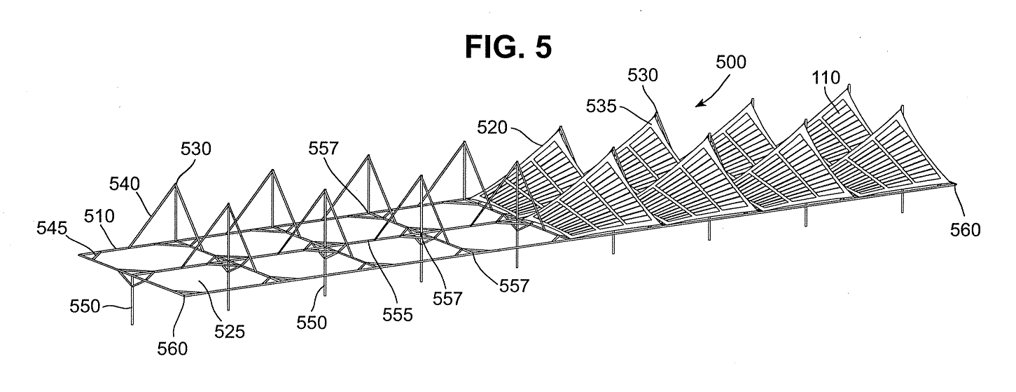

FIG. 5 shows an example of a frame-based structure 500, formed of modular tensile structures, for covering an area, such as, for example, a row of a parking lot. The structure 500 generates electrical power using PV modules 110, as discussed above, and also provides shelter for parked vehicles in the parking lot. The example structure 500 depicted in FIG. 5 is designed to be positioned to cover a single row of head-to-head, pull-in parking. Of course, other configurations may be implemented depending upon the physical layout of the parking lot or other area to be covered.

The structure uses a horizontally-oriented frame 510 to support the membranes 520 (only a few of which are shown here, for clarity), rather than using support poles and cables, as shown in the module of FIG. 1. The horizontal frame 510 is formed of a lattice of square or rectangular frame elements 525, e.g., square frame elements measuring about 20 feet by about 20 feet, each of which has a vertical membrane support member 530 in one corner to support the raised corner 535 of a membrane 520. The structure 500 is modular and scalable, as the size of the horizontal frame 510 can be incrementally increased or decreased based on the arrangement of the parking facility or other area to be covered. The assembly of each individual element of the modular structure 500, e.g., the attachment of the membrane 520 and connection of electrical wiring generally will be uniform throughout the structure, which eases the assembly and installation process.

The horizontal frame 510 may be formed, for example, of tubular, hollow-section steel members, e.g., square-section members having a 8 inch by 8 inch section dimension, with a wall thickness of 5/16 inch. Round or rectangular-section members may also be used. The horizontal frame 510 members may serve as conduits for the power cables running from the membranes 520 to a central power facility. Likewise, the vertical membrane support members 530 may also be formed of tubular, hollow-section steel. Diagonal braces 540 may be used between the vertical membrane support members 530 and the adjacent horizontal frame 510 members to provide increased support for the vertical membrane support members 530. Similarly, braces 545 may be used within each frame opening 525 to strengthen the frame 510.

The horizontal frame 510 is support by a series of base support members 550, which are positioned along the central spine 555 of the horizontal frame 510 lattice, e.g., at each vertex 557 of the lattice along the central spine 555. The base support members 550 may also be formed, for example, of tubular, hollow-section steel. Additional base support members (not shown) may be added at the corners 560 of the horizontal frame 510 lattice at each end of the structure to provide further support. This configuration provides a cantilevered structure over each side of the parking row, which eliminates the need for support members between parking spaces, thereby reducing the possibility of damage to the structure by vehicles and vice versa.

The position of the vertical membrane support members 530 on the horizontal frame 510 may be determined by site-specific characteristics relating to the orientation of the structure relative to the path of the sun. Generally speaking, if the structure 500 is to be erected in an existing parking facility, then the orientation of the structure 500 as a whole will be limited to the row arrangement of the parking lot. Therefore, the position of the vertical membrane support member 530, which typically will be on one of the four corners of each opening 525 of the lattice, will be determined by the direction in which the double-curved membrane 520 should face to maximize the solar energy received. This in effect allows the membrane and array of photovoltaic modules to be rotated in increments of 90° to achieve a desired orientation with respect to the sun.

The frame-based tensile structure 500 of FIG. 5 may also be used in various other applications. In certain applications, it may be desirable to have a base support members 550 in positions other than just along the central spine 555 and outermost corners 560. For example, in certain applications it may be desirable to have a base support member 550 at every, or almost every, vertex 557 of the lattice (i.e., the corners of rectangular or square openings 525 in the horizontal frame). The frame-based configuration of the structure 500 depicted in FIG. 5 may also be used to form larger tensile structures like the one shown in FIG. 4. In such case, the modular tensile structures would be implemented using a horizontal frame having openings, rather than using poles at the corners of each modular structure.

Although the invention has been described and illustrated in the foregoing illustrative embodiments, it is understood that the present disclosure has been made only by way of example, and that numerous changes in the details of implementation of the invention can be made without departing from the spirit and scope of the invention, which is limited only by the claims that follow. Features of the disclosed embodiments can be combined and rearranged in various ways within the scope and spirit of the invention.

What is claimed is:

1. A tensile structure comprising:
a plurality of vertical support members arranged to surround an area, one of the vertical support members being taller than all others of the vertical support members;
a plurality of securing members connected between the vertical support members and ground;
a membrane attached to and extending between the vertical support members to form a roof of the tensile structure, such that one corner of the membrane is raised with respect to the other corners; and
a plurality of flexible photovoltaic devices integrated with the membrane.

2. The tensile structure of claim 1, wherein the membrane is formed of a plurality of elongate sections, each section having concave lengthwise edges and concave end edges.

3. The tensile structure of claim 2, wherein shapes of the concave lengthwise edges and shapes of the end edges of the sections are determined based at least in part on a difference between a length of the taller vertical support member and the other vertical support members.

4. The tensile structure of claim 1, wherein the membrane comprises fabric and a shape of the membrane is compensated for stretching based on stretching characteristics of the fabric.

5. The tensile structure of claim 4, wherein the compensation for stretching is adjusted based on a determination of areas of the membrane that comprise the photovoltaic devices.

6. The tensile structure of claim 5, wherein the adjustment to the compensation for stretching is based on separately computing stretch compensation for areas of the membrane comprising the photovoltaic devices and areas of the membrane without the photovoltaic devices.

7. The tensile structure of claim 5, wherein the adjustment to the compensation for stretching is based on performing an integration, over the area of the membrane, of stretch compensation factors for differential areas of the membrane.

8. The tensile structure of claim 1, wherein the photovoltaic devices are arranged to allow the membrane to be folded without folding the photovoltaic devices.

9. The tensile structure of claim 1, wherein a difference between a length of the taller vertical support member and the other vertical support members is determined based at least in part on a desired solar inclination angle.

10. The tensile structure of claim 1, wherein the photovoltaic devices are arranged in rows and pairs of columns, such that an internal gap within a pair of columns is less that an external gap between pairs of columns.

11. The tensile structure of claim 1, wherein at least one of the securing members comprises a tensioning device configured to apply variable tension to a vertical support member to which it is connected.

12. The tensile structure of claim 1, wherein the flexible photovoltaic devices comprise photovoltaic modules formed of amorphous silicon on a polymer substrate.

13. The tensile structure of claim 1, wherein the flexible photovoltaic devices comprise photovoltaic modules formed of a copper indium gallium selenide thin film.

14. The tensile structure of claim 1, wherein the membrane comprises fabric.

15. The tensile structure of claim 14, wherein the fabric is polyester vinyl.

16. The tensile structure of claim 1, wherein the securing members comprise cables.

17. The tensile structure of claim 1, wherein the securing members comprise webbing belts.

18. A method of constructing a tensile structure, the method comprising:
providing a plurality of vertical support members, one of the vertical support members being taller than all others of the vertical support members;
providing a plurality of securing members connected between the vertical support members and ground;
integrating a plurality of flexible photovoltaic devices with a membrane; and
attaching the membrane to and extending between the vertical support members to form a roof of the tensile structure, such that one corner of the membrane is raised with respect to the other corners.

19. The method of claim 18, wherein the membrane comprises joined sections, and the photovoltaic devices are integrated with the sections before the sections are joined.

20. The method of claim 18, wherein the membrane is formed of a plurality of elongate sections, each section having concave lengthwise edges and concave end edges.

21. The method of claim 18, further comprising determining shapes of the concave lengthwise edges and shapes of the end edges of the sections based at least in part on a difference between a length of the taller vertical support member and the other vertical support members.

22. The method of claim 18, wherein the membrane comprises fabric, and the method further comprises compensating a shape of the membrane for stretching based on stretching characteristics of the fabric.

23. The method of claim 22, further comprising adjusting the compensation for stretching based on a determination of areas of the membrane that comprise the photovoltaic devices.

24. The method of claim 23, wherein the adjustment to the compensation for stretching is based on separately computing stretch compensation for areas of the membrane comprising the photovoltaic devices and areas of the membrane without the photovoltaic devices.

25. The method of claim 23, wherein the adjustment to the compensation for stretching is based on performing an integration, over the area of the membrane, of stretch compensation factors for differential areas of the membrane.

26. The method of claim 18, wherein the photovoltaic devices are arranged to allow the membrane to be folded without bending any of the photovoltaic devices.

27. The method of claim 18, further comprising determining a difference between a length of the taller vertical support member and the other vertical support members based at least in part on a desired solar inclination angle.

28. The method of claim 18, wherein the photovoltaic devices are arranged in rows and pairs of columns, such that an internal gap within a pair of columns is less that an external gap between pairs of columns.

29. The method of claim 18, wherein at least one of the securing members comprises a tensioning device configured to apply variable tension to a vertical support member to which it is connected.

30. A tensile structure comprising:
a horizontal frame having frame elements with vertices, each frame element defining an opening surrounded by horizontal members of the horizontal frame which meet at the vertices;
a plurality of vertical support members, each positioned at a vertex of a frame element;
a plurality of base support members connected at vertices of the horizontal frame along a central portion to support the horizontal frame above the ground;
a plurality of membranes, each membrane attached to one of the frame elements between the vertical support member and the vertices of the frame element to form a portion of a roof of the tensile structure, such that a corner of the membrane attached to the vertical support member is raised with respect to the other corners; and
a plurality of flexible photovoltaic devices integrated with each of the membranes.

31. The tensile structure of claim 30, wherein the membrane is formed of a plurality of elongate sections, each section having concave lengthwise edges and concave end edges.

32. The tensile structure of claim 31, wherein shapes of the concave lengthwise edges and shapes of the end edges of the sections are determined based at least in part on a difference between a length of the taller vertical support member and the other vertical support members.

33. The tensile structure of claim 30, wherein the membrane comprises fabric and a shape of the membrane is compensated for stretching based on stretching characteristics of the fabric.

34. The tensile structure of claim 33, wherein the compensation for stretching is adjusted based on a determination of areas of the membrane that comprise the photovoltaic devices.

35. The tensile structure of claim 34, wherein the adjustment to the compensation for stretching is based on separately computing stretch compensation for areas of the membrane comprising the photovoltaic devices and areas of the membrane without the photovoltaic devices.

36. The tensile structure of claim 34, wherein the adjustment to the compensation for stretching is based on performing an integration, over the area of the membrane, of stretch compensation factors for differential areas of the membrane.

37. The tensile structure of claim 30, wherein the photovoltaic devices are arranged to allow the membrane to be folded without folding the photovoltaic devices.

38. The tensile structure of claim 30, wherein a difference between a length of the taller vertical support member and the other vertical support members is determined based at least in part on a desired solar inclination angle.

39. The tensile structure of claim 30, wherein the photovoltaic devices are arranged in rows and pairs of columns, such that an internal gap within a pair of columns is less that an external gap between pairs of columns.

40. The tensile structure of claim 30, wherein the flexible photovoltaic devices comprise photovoltaic modules formed of amorphous silicon on a polymer substrate.

41. The tensile structure of claim 30, wherein the flexible photovoltaic devices comprise photovoltaic modules formed of a copper indium gallium selenide thin film.

42. The tensile structure of claim 30, wherein the membrane comprises fabric.

43. The tensile structure of claim 42, wherein the fabric is polyester vinyl.

44. A method of constructing a tensile structure, the method comprising:
providing a horizontal frame having frame elements with vertices, each frame element defining an opening surrounded by horizontal members of the horizontal frame which meet at the vertices;
providing a plurality of vertical support members, each positioned at a vertex of a frame element;
providing a plurality of base support members connected at vertices of the horizontal frame along a central portion to support the horizontal frame above the ground;
integrating a plurality of flexible photovoltaic devices with each membrane of a plurality of membranes; and
attaching each membrane to one of the frame elements between the vertical support member and the vertices of the frame element to form a portion of a roof of the tensile structure, such that a corner of the membrane attached to the vertical support member is raised with respect to the other corners.

45. The method of claim 44, wherein the membrane comprises joined sections, and the photovoltaic devices are integrated with the sections before the sections are joined.

46. The method of claim 44, wherein the membrane is formed of a plurality of elongate sections, each section having concave lengthwise edges and concave end edges.

47. The method of claim 44, further comprising determining shapes of the concave lengthwise edges and shapes of the end edges of the sections based at least in part on a difference between a length of the taller vertical support member and the other vertical support members.

48. The method of claim 44, wherein the membrane comprises fabric, and the method further comprises compensating a shape of the membrane for stretching based on stretching characteristics of the fabric.

49. The method of claim 48, further comprising adjusting the compensation for stretching based on a determination of areas of the membrane that comprise the photovoltaic devices.

50. The method of claim 49, wherein the adjustment to the compensation for stretching is based on separately computing stretch compensation for areas of the membrane comprising the photovoltaic devices and areas of the membrane without the photovoltaic devices.

51. The method of claim 49, wherein the adjustment to the compensation for stretching is based on performing an integration, over the area of the membrane, of stretch compensation factors for differential areas of the membrane.

52. The method of claim 44, wherein the photovoltaic devices are arranged to allow the membrane to be folded without bending any of the photovoltaic devices.

53. The method of claim 44, further comprising determining a difference between a length of the taller vertical support member and the other vertical support members based at least in part on a desired solar inclination angle.

54. The method of claim 44, wherein the photovoltaic devices are arranged in rows and pairs of columns, such that an internal gap within a pair of columns is less that an external gap between pairs of columns.

55. A tensile structure comprising:
a plurality of vertical support members arranged to surround a plurality of adjoining areas, one of the vertical support members of each area being taller than all others of the vertical support members of the area;
a plurality of securing members connected between the vertical support members and ground;
a plurality of membranes, each membrane attached to and extending between the vertical support members of one of the areas to form a portion of a roof of the tensile structure, such that one corner of the membrane is raised with respect to the other corners; and
a plurality of flexible photovoltaic devices integrated with each of the membranes.

56. The tensile structure of claim 55, wherein the vertical support members of adjoining areas are shared such that a portion of the vertical support members are attached to more than one membrane.

57. The tensile structure of claim 56, wherein at least one of the taller vertical support members comprises a lower connection point positioned a distance below a top connection point, such that the taller vertical support is attached by the top connection point to a raised corner of a membrane of one area and is attached by the lower connection point to a corner other than the raised corner of a membrane of an adjoining area.

58. The tensile structure of claim 55, wherein the membrane is formed of a plurality of elongate sections, each section having concave lengthwise edges and concave end edges.

59. The tensile structure of claim 58, wherein shapes of the concave lengthwise edges and shapes of the end edges of the sections are determined based at least in part on a difference between a length of the taller vertical support member and the other vertical support members.

60. The tensile structure of claim 55, wherein the membrane comprises fabric and a shape of the membrane is compensated for stretching based on stretching characteristics of the fabric.

61. The tensile structure of claim 60, wherein the compensation for stretching is adjusted based on a determination of areas of the membrane that comprise the photovoltaic devices.

62. The tensile structure of claim 61, wherein the adjustment to the compensation for stretching is based on separately computing stretch compensation for areas of the membrane comprising the photovoltaic devices and areas of the membrane without the photovoltaic devices.

63. The tensile structure of claim 61, wherein the adjustment to the compensation for stretching is based on performing an integration, over the area of the membrane, of stretch compensation factors for differential areas of the membrane.

64. The tensile structure of claim 55, wherein the photovoltaic devices are arranged to allow the membrane to be folded without folding the photovoltaic devices.

65. The tensile structure of claim 55, wherein a difference between a length of the taller vertical support member and the other vertical support members is determined based at least in part on a desired solar inclination angle.

66. The tensile structure of claim 55, wherein the photovoltaic devices are arranged in rows and pairs of columns, such that an internal gap within a pair of columns is less that an external gap between pairs of columns.

67. The tensile structure of claim 55, wherein at least one of the securing members comprises a tensioning device configured to apply variable tension to a vertical support member to which it is connected.

68. The tensile structure of claim 55, wherein the flexible photovoltaic devices comprise photovoltaic modules formed of amorphous silicon on a polymer substrate.

69. The tensile structure of claim 55, wherein the flexible photovoltaic devices comprise photovoltaic modules formed of a copper indium gallium selenide thin film.

70. The tensile structure of claim 55, wherein the membrane comprises fabric.

71. The tensile structure of claim 70, wherein the fabric is polyester vinyl.

72. The tensile structure of claim 55, wherein the securing members comprise cables.

73. The tensile structure of claim 55, wherein the securing members comprise webbing belts.

74. A method of constructing a tensile structure, the method comprising:
providing a plurality of vertical support members arranged to surround a plurality of adjoining areas, one of the vertical support members of each area being taller than all others of the vertical support members of the area;
providing a plurality of securing members connected between the vertical support members and ground;
integrating a plurality of flexible photovoltaic devices with each of the membranes; and
providing a plurality of membranes, each membrane attached to and extending between the vertical support members of one of the areas to form a portion of a roof of the tensile structure, such that one corner of the membrane is raised with respect to the other corners.

75. The method of claim 74, wherein the vertical support members of adjoining areas are shared such that a portion of the vertical support members are attached to more than one membrane.

76. The method of claim 74, wherein at least one of the taller vertical support members comprises a lower connection point positioned a distance below a top connection point, such that the taller vertical support is attached by the top connection point to a raised corner of a membrane of one area and is attached by the lower connection point to a corner other than the raised corner of a membrane of an adjoining area.

77. The method of claim 74, wherein the membrane comprises joined sections, and the photovoltaic devices are integrated with the sections before the sections are joined.

78. The method of claim 74, wherein the membrane is formed of a plurality of elongate sections, each section having concave lengthwise edges and concave end edges.

79. The method of claim 74, further comprising determining shapes of the concave lengthwise edges and shapes of the end edges of the sections based at least in part on a difference between a length of the taller vertical support member and the other vertical support members.

80. The method of claim 74, wherein the membrane comprises fabric, and the method further comprises compensating a shape of the membrane for stretching based on stretching characteristics of the fabric.

81. The method of claim 80, further comprising adjusting the compensation for stretching based on a determination of areas of the membrane that comprise the photovoltaic devices.

82. The method of claim 81, wherein the adjustment to the compensation for stretching is based on separately computing stretch compensation for areas of the membrane comprising the photovoltaic devices and areas of the membrane without the photovoltaic devices.

83. The method of claim 81, wherein the adjustment to the compensation for stretching is based on performing an integration, over the area of the membrane, of stretch compensation factors for differential areas of the membrane.

84. The method of claim 74, wherein the photovoltaic devices are arranged to allow the membrane to be folded without bending any of the photovoltaic devices.

85. The method of claim 74, further comprising determining a difference between a length of the taller vertical support member and the other vertical support members based at least in part on a desired solar inclination angle.

86. The method of claim 74, wherein the photovoltaic devices are arranged in rows and pairs of columns, such that an internal gap within a pair of columns is less that an external gap between pairs of columns.

87. The method of claim 74, wherein at least one of the securing members comprises a tensioning device configured to apply variable tension to a vertical support member to which it is connected.

88. A tensile structure comprising:
a vertical support member;
at least one securing member connected between the vertical support member and ground;
a membrane having one corner attached to the vertical support member and all others of the corners attached to points on the ground, to form a roof of the tensile structure, such that the corner of the membrane attached to the vertical support member is raised with respect to the other corners; and
a plurality of flexible photovoltaic devices integrated with the membrane.

89. The tensile structure of claim 88, wherein the membrane is formed of a plurality of elongate sections, each section having concave lengthwise edges and concave end edges.

90. The tensile structure of claim 89, wherein shapes of the concave lengthwise edges and shapes of the end edges of the sections are determined based at least in part on a difference between a length of the taller vertical support member and the other vertical support members.

91. The tensile structure of claim 88, wherein the membrane comprises fabric and a shape of the membrane is compensated for stretching based on stretching characteristics of the fabric.

92. The tensile structure of claim 91, wherein the compensation for stretching is adjusted based on a determination of areas of the membrane that comprise the photovoltaic devices.

93. The tensile structure of claim 92, wherein the adjustment to the compensation for stretching is based on separately computing stretch compensation for areas of the membrane comprising the photovoltaic devices and areas of the membrane without the photovoltaic devices.

94. The tensile structure of claim 92, wherein the adjustment to the compensation for stretching is based on performing an integration, over the area of the membrane, of stretch compensation factors for differential areas of the membrane.

95. The tensile structure of claim 88, wherein the photovoltaic devices are arranged to allow the membrane to be folded without folding the photovoltaic devices.

96. The tensile structure of claim 88, wherein a difference between a length of the taller vertical support member and the other vertical support members is determined based at least in part on a desired solar inclination angle.

97. The tensile structure of claim 88, wherein the photovoltaic devices are arranged in rows and pairs of columns, such that an internal gap within a pair of columns is less that an external gap between pairs of columns.

98. The tensile structure of claim 88, wherein at least one of the securing members comprises a tensioning device configured to apply variable tension to a vertical support member to which it is connected.

99. The tensile structure of claim 88, wherein the flexible photovoltaic devices comprise photovoltaic modules formed of amorphous silicon on a polymer substrate.

100. The tensile structure of claim 88, wherein the flexible photovoltaic devices comprise photovoltaic modules formed of a copper indium gallium selenide thin film.

101. The tensile structure of claim 88, wherein the membrane comprises fabric.

102. The tensile structure of claim 101, wherein the fabric is polyester vinyl.

103. The tensile structure of claim 88, wherein the securing members comprise cables.

104. The tensile structure of claim 88, wherein the securing members comprise webbing belts.

105. A method of constructing a tensile structure, the method comprising:
providing a vertical support member;
providing at least one securing member connected between the vertical support member and ground;
integrating a plurality of flexible photovoltaic devices with a membrane; and
attaching one corner of the membrane to the vertical support member and attaching all others of the corners to points on the ground, to form a roof of the tensile structure, such that the corner of the membrane attached to the vertical support member is raised with respect to the other corners.

106. The method of claim 105, wherein the membrane comprises joined sections, and the photovoltaic devices are integrated with the sections before the sections are joined.

107. The method of claim 105, wherein the membrane is formed of a plurality of elongate sections, each section having concave lengthwise edges and concave end edges.

108. The method of claim 105, further comprising determining shapes of the concave lengthwise edges and shapes of the end edges of the sections based at least in part on a length of the vertical support member.

109. The method of claim 105, wherein the membrane comprises fabric, and the method further comprises compensating a shape of the membrane for stretching based on stretching characteristics of the fabric.

110. The method of claim 109, further comprising adjusting the compensation for stretching based on a determination of areas of the membrane that comprise the photovoltaic devices.

111. The method of claim 110, wherein the adjustment to the compensation for stretching is based on separately computing stretch compensation for areas of the membrane comprising the photovoltaic devices and areas of the membrane without the photovoltaic devices.

112. The method of claim 110, wherein the adjustment to the compensation for stretching is based on performing an integration, over the area of the membrane, of stretch compensation factors for differential areas of the membrane.

113. The method of claim 105, wherein the photovoltaic devices are arranged to allow the membrane to be folded without bending any of the photovoltaic devices.

114. The method of claim 105, further comprising determining a length of the vertical support member based at least in part on a desired solar inclination angle.

115. The method of claim 105, wherein the photovoltaic devices are arranged in rows and pairs of columns, such that an internal gap within a pair of columns is less that an external gap between pairs of columns.

116. The method of claim 105, wherein at least one of the securing members comprises a tensioning device configured to apply variable tension to the vertical support member.
